(19) United States
(12) Patent Application Publication
(10) Pub. No.: US 2024/0341137 A1
(43) Pub. Date: Oct. 10, 2024

(54) DISPLAY DEVICE AND METHOD OF MANUFACTURING THE SAME

(71) Applicant: Samsung Display Co., LTD., Yongin-si (KR)

(72) Inventor: HYUNEOK SHIN, Yongin-si (KR)

(73) Assignee: Samsung Display Co., LTD., Yongin-si (KR)

(21) Appl. No.: 18/398,732

(22) Filed: Dec. 28, 2023

(30) Foreign Application Priority Data
Apr. 10, 2023 (KR) 10-2023-0046952

(51) Int. Cl. H10K 59/131; H10K 59/12

(52) U.S. Cl. CPC H10K 59/131; H10K 59/1201

(57) ABSTRACT

A display device includes an active layer disposed on a substrate, and a conductive pattern disposed on or under the active layer and including an upper conductive layer having a first line width in a direction and a lower conductive layer including a first metal layer disposed under the upper conductive layer and a capping layer disposed between the upper conductive layer and the first metal layer and having a second line width in the direction greater than the first line width.

### CROSS REFERENCE TO RELATED APPLICATION(S)

This application claims priority to and benefits of Korean Patent Application No. 10-2023-0046952 under 35 U.S.C. § 119, filed on Apr. 10, 2023, in the Korean Intellectual Property Office (KIPO), the entire contents of which are incorporated herein by reference.

### BACKGROUND

### 1. Technical Field

Embodiments relate to a display device and a method of manufacturing the display device.

### 2. Description of the Related Art

A display device is a device that displays an image to provide visual information to a user. Among display devices, an organic light emitting diode display (OLED display) has recently been attracting attention.

Since the organic light emitting display device has self-luminous properties and does not require a separate light source unlike a liquid crystal display device, thickness and weight may be reduced. The organic light emitting diode display exhibits high quality characteristics such as low power consumption, high luminance, high response speed, and the like.

### SUMMARY

The disclosure provides a display device realizing high resolution and having improved durability.

The disclosure provides a method for manufacturing the display device.

A display device according to an embodiment may include an active layer disposed on a substrate, and a conductive pattern disposed on or under the active layer and including an upper conductive layer having a first line width in a direction and a lower conductive layer including a first metal layer disposed under the upper conductive layer and a capping layer disposed between the upper conductive layer and the first metal layer and having a second line width in the direction greater than the first line width.

In an embodiment, a side surface of the conductive pattern may have a step.

In an embodiment, the upper conductive layer may include copper, and the first metal layer may include aluminum.

In an embodiment, a difference between the second line width and the first line width may be in a range of about 0.3 micrometers to about 0.9 micrometers.

In an embodiment, a thickness of the upper conductive layer may be in a range of about 1500 Å to about 3000 Å, and a thickness of the lower conductive layer may be in a range of about 1500 Å to about 3000 Å.

In an embodiment, the capping layer may include a titanium alloy.

In an embodiment, the capping layer may include titanium nitride.

In an embodiment, the lower conductive layer may further include a second metal layer disposed under the first metal layer.

In an embodiment, the second metal layer may include titanium.

In an embodiment, the display device may further include an insulating layer disposed between the active layer and the conductive pattern. The active layer and the conductive pattern may be spaced apart from each other by the insulating layer.

A method of manufacturing a display device according to an embodiment may include forming an active layer on a substrate and forming a conductive pattern on or under the active layer, and the forming of the conductive pattern may include forming a preliminary lower conductive layer including a first preliminary metal layer and a preliminary capping layer disposed on the first preliminary metal layer, forming a preliminary upper conductive layer on the preliminary lower conductive layer, forming an upper conductive layer having a first line width in a direction by patterning the preliminary upper conductive layer, and forming a lower conductive layer including a first metal layer disposed under the upper conductive layer and a capping layer disposed between the upper conductive layer and the first metal layer and having a second line width in the direction greater than the first line width by patterning the preliminary lower conductive layer.

In an embodiment, the forming of the upper conductive layer may include etching a portion of the preliminary upper conductive layer through a wet etching process, and the forming of the lower conductive layer may include etching a portion of the preliminary lower conductive layer through a dry etching process.

In an embodiment, an etching rate of the preliminary capping layer in the wet etching process may be less than an etching rate of the preliminary upper conductive layer in the wet etching process.

In an embodiment, the preliminary capping layer and the first preliminary metal layer may be etched together through the dry etching process.

In an embodiment, the preliminary upper conductive layer may include copper, and the first preliminary metal layer may include aluminum.

In an embodiment, the preliminary capping layer may include a titanium alloy.

In an embodiment, a difference between the second line width and the first line width may be in a range of about 0.3 micrometer to about 0.9 micrometer.

In an embodiment, the preliminary lower conductive layer may further include a second preliminary metal layer disposed under the first preliminary metal layer, and the lower conductive layer may further include a second metal layer disposed under the first metal layer after the forming of the lower conductive layer.

In an embodiment, the second preliminary metal layer may include titanium.

In an embodiment, after the forming of the conductive pattern, a side surface of the conductive pattern may have a step.

In the display device according to embodiments, the display device may include a conductive pattern disposed on or under the active layer, and the conductive pattern may have a multi-layered structure in which a lower conductive layer and an upper conductive layer are sequentially stacked. The lower conductive layer may have a high etching rate in the dry etching process, but a low etching rate in the wet etching process. Conversely, the upper conductive layer may have a high etching rate in the wet etching process, but a low etching rate in the dry etching process.

Accordingly, a line width of the lower conductive layer may be greater than a line width of the upper conductive layer. For example, a side surface of the conductive pattern may have a step. Accordingly, step coverage of an insulating layer covering the conductive pattern may be improved. Thus, cracks in the insulating layer may be prevented or reduced, and damage to the conductive pattern may be prevented or reduced. Accordingly, durability of the display device may be improved.

Also, the upper conductive layer may have low resistance characteristics. Accordingly, a resistance of the conductive pattern may be reduced due to the low resistance characteristics of the upper conductive layer, and at a same time, in the process of forming the lower conductive layer using the dry etching process, a fine line width of the conductive pattern may be readily realized. Therefore, high resolution may be realized in the display device and display quality may be improved.

It is to be understood that both the foregoing general description and the following detailed description are exemplary and explanatory and are intended to provide further explanation of the disclosure as claimed.

### BRIEF DESCRIPTION OF THE DRAWINGS

Illustrative, non-limiting embodiments will be more clearly understood from the following detailed description taken in conjunction with the accompanying drawings.

FIG. 1 is a schematic plan view illustrating a display device according to an embodiment.

FIG. 2 is a schematic cross-sectional view taken along line I-I′ of FIG. 1 according to an embodiment.

FIG. 3 is a schematic cross-sectional view illustrating enlarged area A of FIG. 2 according to an embodiment.

FIG. 4 is a schematic cross-sectional view illustrating enlarged area A of FIG. 2 according to an embodiment.

FIGS. 5 to 13 are schematic cross-sectional views illustrating a manufacturing method of a display device according to an embodiment.

FIG. 14 is a schematic cross-sectional view taken along line I-I′ of FIG. 1 according to an embodiment.

FIG. 15 is a schematic cross-sectional view illustrating enlarged area E of FIG. 14 according to an embodiment.

FIG. 16 is a schematic cross-sectional view illustrating enlarged area E of FIG. 14 according to an embodiment.

FIGS. 17 to 25 are schematic cross-sectional views illustrating a manufacturing method of a display device according to an embodiment.

FIG. 26 is a schematic cross-sectional view taken along line I-I′ of FIG. 1 according to an embodiment.

FIG. 27 is a schematic cross-sectional view taken along line I-I′ of FIG. 1 according to an embodiment.

FIG. 28 is a schematic cross-sectional view taken along line I-I′ of FIG. 1 according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” “including,” “has,” and/or “having,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

When an element, such as a layer, is referred to as being “on” or “connected to” another element or layer, it may be directly on or connected to the other element or layer or intervening elements or layers may be present. When, however, an element or layer is referred to as being “directly on” or “directly connected to” another element or layer, there are no intervening elements or layers present. To this end, the term “connected” may refer to physical, electrical, and/or fluid connection, with or without intervening elements.

It will be understood that when an element such as a layer, film, region, or substrate is referred to as being “on” or “above” another element, it can be directly on the other element or intervening element(s) may also be present. In contrast, when an element is referred to as being “directly on” another element, no intervening elements are present.

When a component is described herein to “connect” another component to the other component or to be “connected to” other components, the components may be connected to each other as separate elements, or the components may be integral with each other.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

Spatially relative terms, such as “under,” “lower,” “above,” “upper,” “side,” and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The display surface may be parallel to a surface defined by a first direction DR1 and a second direction DR2. A normal direction of the display surface, i.e., a thickness direction of the display device DD, may indicate a Z axis. In this specification, an expression of “when viewed from the top or in a plan view” may represent a case when viewed in the Z axis. Hereinafter, a front surface (or a top surface) and a rear surface (or a bottom surface) of each of layers or units may be distinguished by the Z axis. However, directions indicated by X, Y, and Z axes may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

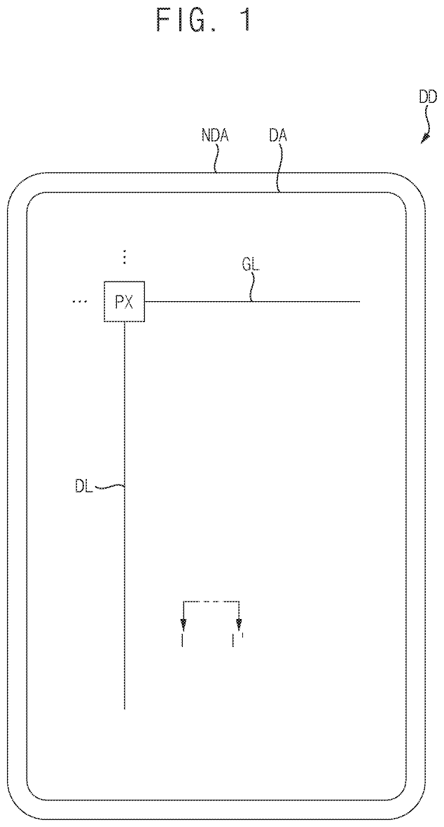

FIG. 1 is a schematic plan view illustrating a display device according to an embodiment.

Referring to FIG. 1, a display device DD may include a display area DA and a non-display area NDA. The display area DA may be an area displaying an image. In an embodiment, the display area DA may have a rectangular shape in a plan view. Referring to FIG. 1, in an embodiment, the display area DA may have a rectangular shape with rounded corners in a plan view. However, the shape of the display area DA is not limited thereto, and in another embodiment, the display area DA may have other shapes such as a circular shape, an elliptical shape, a polygonal shape, and the like in a plan view.

The non-display area NDA may be disposed adjacent to the display area DA. The non-display area NDA may surround at least a portion of the display area DA. The non-display area NDA may be an area not displaying an image. In an embodiment, drivers for displaying an image of the display area DA may be disposed in the non-display area NDA.

Pixels PX may be arranged in a matrix in the display area DA. Signal lines such as a gate line GL, a data line DL, and the like may be disposed in the display area DA. The signal lines such as the gate line GL, the data line DL, and the like may be electrically connected to each of the pixels PX. Each of the pixels PX may receive a gate signal, a data signal, and the like from the signal lines.

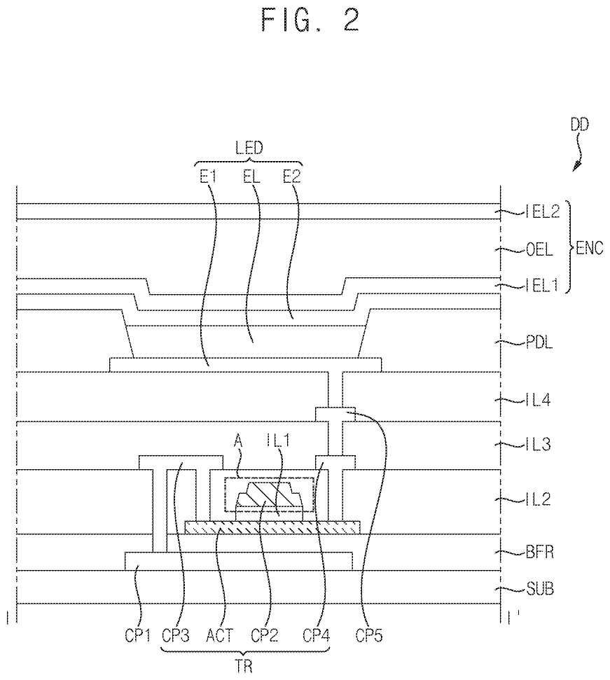

FIG. 2 is a schematic cross-sectional view taken along line I-I′ of FIG. 1 according to an embodiment.

Referring to FIGS. 1 and 2, the display device DD may include a substrate SUB, a first conductive pattern CP1, a buffer layer BFR, multiple insulating layers IL1, IL2, IL3, and IL4, an active layer ACT, a second conductive pattern CP2, a third conductive pattern CP3, a fourth conductive pattern CP4, a fifth conductive pattern CP5, a pixel defining layer PDL, a light emitting element LED, and an encapsulation layer ENC. The light emitting element LED may include a first electrode E1, a light emitting layer EL, and a second electrode E2.

The substrate SUB may be a base substrate, a base member, or the like, and may include an insulating material such as a polymer resin or the like. For example, the substrate SUB may be a flexible substrate capable of being bent, folded, or rolled. In an embodiment, the substrate SUB may include a flexible material, a rigid material, the like, or a combination thereof.

The first conductive pattern CP1 may be disposed on the substrate SUB.

The buffer layer BFR may be disposed on the substrate SUB (and the first conductive pattern). The buffer layer BFR may cover the first conductive pattern CP1. The first conductive pattern CP1 and the buffer layer BFR may prevent or reduce diffusion of metal atoms or impurities from the substrate SUB into the active layer ACT.

The active layer ACT may be disposed on the buffer layer BFR. The active layer ACT may overlap the first conductive pattern CP1 in a plan view. The active layer ACT may be spaced apart from the first conductive pattern CP1 by the buffer layer BFR. For example, the active layer ACT may not contact the first conductive pattern CP1 by the buffer layer BFR.

In an embodiment, the active layer ACT may include an oxide semiconductor. For example, the oxide semiconductor included in the active layer ACT may include: an unitary metal oxide such as indium (In) oxide, tin (Sn) oxide, zinc (Zn) oxide, the like, or a combination thereof; a binary metal oxide such as In—Zn-based oxide, Sn—Zn-based oxide, Al—Zn-based oxide, Zn—Mg-based oxide, Sn—Mg-based oxide, In—Mg-based oxide, In—Ga-based oxide, the like, or a combination thereof; a ternary metal oxide such as In—Ga—Zn-based oxide, In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, the like, or a combination thereof; a quaternary metal oxide such as In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, In—Hf—Al—Zn-based oxide, the like, or a combination thereof. For example, the active layer ACT may include Indium-Gallium-Zinc Oxide (IGZO).

In an embodiment, the active layer ACT may include a silicon semiconductor. For example, the silicon semiconductor material included in the active layer ACT may include amorphous silicon, polycrystalline silicon, or the like.

The first insulating layer IL1 may be disposed on the active layer ACT (e.g., a portion of the active layer ACT). The first insulating layer IL1 may overlap the active layer ACT in a plan view and may have an island shape in a plan view. However, the disclosure is not necessarily limited thereto, and in another embodiment, the first insulating layer IL1 may cover the active layer ACT and may be disposed on the buffer layer BFR. In an embodiment, the first insulating layer IL1 may include an inorganic material.

The second conductive pattern CP2 may be disposed on the first insulating layer IL1. In an embodiment, the second conductive pattern CP2 may overlap the active layer ACT in a plan view. However, the disclosure is not limited thereto, and in another embodiment, the second conductive pattern CP2 may be a portion of the gate line. Accordingly, a material forming the second conductive pattern CP2 and a thickness of the second conductive pattern CP2 and a material forming the gate line and a thickness of the gate line may be substantially the same. Also, the active layer ACT may be spaced apart from the second conductive pattern CP2 by the first insulating layer IL1. In an embodiment, the active layer ACT may not contact the second conductive pattern CP2 by the first insulating layer IL1.

The second insulating layer IL2 may be disposed on the buffer layer BFR and the active layer ACT. The second insulating layer IL2 may cover the active layer ACT, the first insulating layer IL1, and the second conductive pattern CP2, and may be disposed with substantially a same thickness along a profile of the active layer ACT, the first insulating layer IL1, and the second conductive pattern CP2. However, the disclosure is not limited thereto.

The third conductive pattern CP3 and the fourth conductive pattern CP4 may be disposed on the second insulating layer IL2. The third conductive pattern CP3 may contact the first conductive pattern CP1 through first contact holes formed in the first and second insulating layers IL1 and IL2. Also, the third conductive pattern CP3 may contact the active layer ACT through a second contact hole formed in the second insulating layer IL2. The fourth conductive pattern CP4 may contact the active layer ACT through a third contact hole formed in the second insulating layer IL2. However, the disclosure is not limited thereto. In another embodiment, the fourth conductive pattern CP4 may contact the first conductive pattern CP1 through the first contact hole formed in the first and second insulating layers IL1 and IL2 and may contact the active layer ACT through the second contact hole formed in the second insulating layer IL2. Also, the third conductive pattern CP3 may contact the active layer ACT through the third contact hole formed in the second insulating layer IL2.

In an embodiment, the active layer ACT, the second conductive pattern CP2, the third conductive pattern CP3, and the fourth conductive pattern CP4 may form a transistor TR. However, the disclosure is not necessarily limited thereto.

The third insulating layer IL3 may be disposed on the second insulating layer IL2. The third insulating layer IL3 may cover the third and fourth conductive patterns CP3 and CP4 and may have a substantially flat upper surface without creating a step around (or adjacent to) the third and fourth conductive patterns CP3 and CP4. In an embodiment, the third insulating layer IL3 may include an organic material.

The fifth conductive pattern CP5 may be disposed on the third insulating layer IL3. The fifth conductive pattern CP5 may contact the third conductive pattern CP3 or the fourth conductive pattern CP4 through a fourth contact hole formed in the third insulating layer IL3.

A fourth insulating layer IL4 may be disposed on the third insulating layer IL3 (and the fifth conductive pattern CP5). The fourth insulating layer IL4 may cover the fifth conductive pattern CP5 and may have a substantially flat upper surface without creating a step around (or adjacent to) the fifth conductive pattern CP5. In an embodiment, the fourth insulating layer IL4 may include an organic material.

The first electrode E1 may be disposed on the fourth insulating layer IL4. The first electrode E1 may have light reflection or transmission properties. In an embodiment, the first electrode E1 may include a metal.

The first electrode E1 may contact the fifth conductive pattern CP5 through a fifth contact hole formed in the fourth insulating layer IL4. Through the fifth conductive pattern C, the first electrode E1 may be electrically connected to the transistor TR.

The pixel defining layer PDL may be disposed on the fourth insulating layer IL4 (and both edges of the first electrode E1), and an opening exposing an upper surface of the first electrode E1 may be defined in the pixel defining layer PDL. In an embodiment, the pixel defining layer PDL may include an organic material or an inorganic material.

The light emitting layer EL may be disposed on the first electrode E1 (e.g., a portion of the first electrode E1). The light emitting layer EL may be disposed in the opening formed in the pixel defining layer PDL. For example, the light emitting layer EL may be disposed in the opening of the pixel defining layer PDL. In an embodiment, the light emitting layer EL may have a multi-layers structure including a hole injection layer, a hole transport layer, an organic emission layer, an electron transport layer, and an electron injection layer. The light emitting layer EL may include an organic emission layer including an organic light emitting material.

The second electrode E2 may cover the light emitting layer EL and may be disposed on the pixel defining layer PDL (and the light emitting layer EL). In an embodiment, the second electrode E2 may have a plate shape. Also, the second electrode E2 may have light transmission or reflection properties. In an embodiment, the second electrode E2 may include a metal.

The encapsulation layer ENC may prevent or reduce penetration of moisture and oxygen from an outside into the light emitting element LED. For example, the encapsulation layer ENC may include a first inorganic encapsulation layer IEL1, an organic encapsulation layer OEL, and a second inorganic encapsulation layer IEL2 which are sequentially stacked.

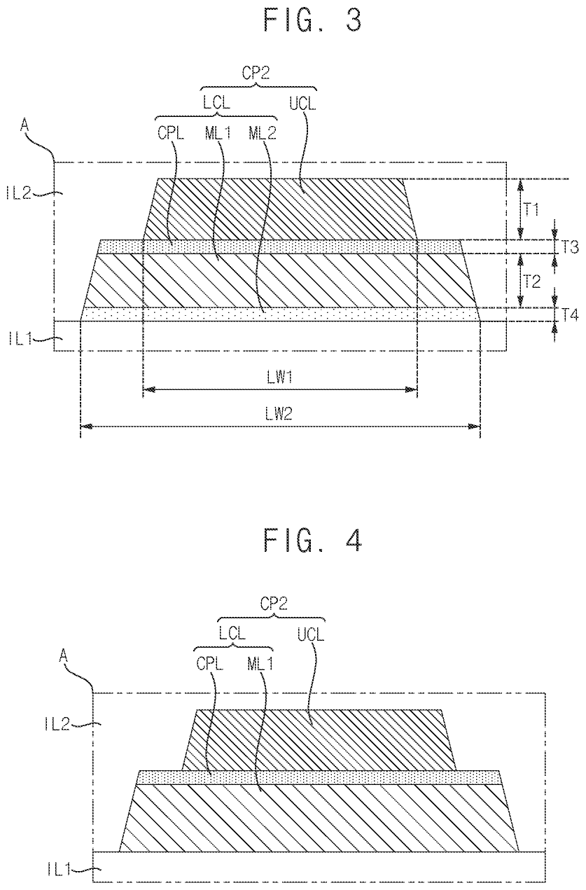

FIG. 3 is a schematic cross-sectional view illustrating enlarged area A of FIG. 2 according to an embodiment. For example, FIG. 3 is a schematic cross-sectional view illustrating the second conductive pattern CP2 according to an embodiment.

Referring to FIGS. 1 to 3, the second conductive pattern CP2 may include an upper conductive layer UCL and a lower conductive layer LCL. The lower conductive layer LCL may be disposed on the first insulating layer IL1, and the upper conductive layer UCL may be disposed on the lower conductive layer LCL. For example, the second conductive pattern CP2 may have a multi-layered structure in which the lower conductive layer LCL and the upper conductive layer UCL are sequentially stacked.

In an embodiment, the upper conductive layer UCL may have a first line width LW1, and the lower conductive layer LCL may have a second line width LW2 greater than the first line width LW1. The first line width LW1 may be a distance between ends of the upper conductive layer UCL in a cross-sectional view, and the second line width LW2 may be a distance between ends of the lower conductive layer LCL in a cross-sectional view.

For example, the upper conductive layer UCL may expose a portion of an upper surface of the lower conductive layer LCL and may be disposed on the lower conductive layer LCL. For example, a side surface of the second conductive pattern CP2 may have a step. Accordingly, a step coverage of the second insulating layer IL2 covering the second conductive pattern CP2 may be improved. Accordingly, cracks of the second insulating layer IL2 may be prevented or reduced, and damage to the second conductive pattern CP2 may be prevented or reduced. Accordingly, durability of the display device DD may be improved.

In an embodiment, a difference between the second line width LW2 of the lower conductive layer LCL and the first line width LW1 of the upper conductive layer UCL may be in a range of about 0.3 micrometers to about 0.9 micrometers. In an embodiment, the difference between the second line width LW2 of the lower conductive layer LCL and the first line width LW1 of the upper conductive layer UCL may be in a range of about 0.5 micrometers to about 0.6 micrometers. For example, the difference between the second line width LW2 of the lower conductive layer LCL and the first line width LW1 of the upper conductive layer UCL may be about 0.5 micrometers. In case that the difference between the second line width LW2 of the lower conductive layer LCL and the first line width LW1 of the upper conductive layer UCL satisfies the above range, a step coverage of the second insulating layer IL2 may be further improved. Accordingly, durability of the display device DD may be further improved.

In an embodiment, the upper conductive layer UCL may include copper (Cu). As the upper conductive layer UCL includes copper (Cu), resistance of the second conductive pattern CP2 may be reduced. Therefore, high resolution may be realized in the display device DD and display quality may be improved. Since the upper conductive layer UCL includes copper (Cu), in a process of forming the upper conductive layer UCL, the first line width LW1 of the upper conductive layer UCL may be readily adjusted to be less than the second line width LW2 of the lower conductive layer LCL. However, a material included in the upper conductive layer UCL is not necessarily limited thereto.

In an embodiment, a first thickness T1 of the upper conductive layer UCL may be in a range of about 1500 Å to about 3000 Å. In an embodiment, the first thickness T1 of the upper conductive layer UCL may be in a range of about 1500 Å to about 2000 Å. For example, the first thickness T1 of the upper conductive layer UCL may be about 1500 Å. In case that the first thickness T1 of the upper conductive layer UCL satisfies the above range, the second conductive pattern CP2 may be readily manufactured in the process of manufacturing the display device DD.

In case that the first thickness T1 of the upper conductive layer UCL satisfies the above range, the first line width LW1 of the upper conductive layer UCL may be readily adjusted to be less than the second line width LW2 of the lower conductive layer LCL. However, the first thickness T1 of the upper conductive layer UCL is not necessarily limited thereto.

The lower conductive layer LCL may include a capping layer CPL, a first metal layer ML1, and a second metal layer ML2. For example, the lower conductive layer LCL may have a three-layer structure in which the second metal layer ML2, the first metal layer ML1, and the capping layer CPL are sequentially stacked. For example, the second conductive pattern CP2 may have a four-layer structure in which the second metal layer ML2, the first metal layer ML1, the capping layer CPL, and the upper conductive layer UCL are sequentially stacked.

The first metal layer ML1 may be disposed under the upper conductive layer UCL. In an embodiment, the first metal layer ML1 may include aluminum (Al). As the first metal layer ML1 includes aluminum (Al), the second line width LW2 of the lower conductive layer LCL may be readily adjusted. For example, the line width of the second conductive pattern CP2 may be readily adjusted. Therefore, a fine line width of the second conductive pattern CP2 may be readily implemented. As the first metal layer ML1 includes aluminum (Al), in a process of forming the lower conductive layer LCL, the second line width LW2 of the lower conductive layer LCL may be readily controlled to be greater than the first line width LW1 of the upper conductive layer UCL. However, a material included in the first metal layer ML1 is not necessarily limited thereto.

In an embodiment, a second thickness T2 of the first metal layer ML1 may be in a range of about 1500 Å to about 3000 Å. In an embodiment, a first thickness T1 of the upper conductive layer UCL may be in a range of about 1500 Å to about 2000 Å. For example, the second thickness T2 of the first metal layer ML1 may be about 1500 Å. As the second thickness T2 of the first metal layer ML1 satisfies the above range, a fine line width of the lower conductive layer LCL may be more readily realized, and in the process of manufacturing the display device DD, the conductive pattern CP2 may be readily manufactured. However, the second thickness T2 of the first metal layer ML1 is not necessarily limited thereto.

The capping layer CPL may be disposed between the first metal layer ML1 and the upper conductive layer UCL. For example, the first metal layer ML1 and the upper conductive layer UCL may be spaced apart from each other by the capping layer CPL. For example, the upper conductive layer UCL may not contact the first metal layer ML1 by the capping layer CPL.

The capping layer CPL may prevent or reduce a phenomenon in which a material of the upper conductive layer UCL is diffused into the first metal layer ML1 or a material of the first metal layer ML1 is diffused into the upper conductive layer UCL. For example, the capping layer CPL may prevent or reduce a phenomenon in which the material of the first metal layer ML1 and the material of the upper conductive layer UCL are mixed with each other. Accordingly, the capping layer CPL may prevent or reduce a phenomenon in which a resistance of the second conductive pattern CP2 is increased by mixing the material of the first metal layer ML1 and the material of the upper conductive layer UCL. Therefore, high resolution may be realized in the display device DD and display quality may be improved.

In an embodiment, the capping layer CPL may include a titanium alloy. For example, the titanium alloy included in the capping layer CPL may be titanium nitride (TiN). In case that the capping layer CPL includes titanium nitride (TiN), a phenomenon in which the material of the first metal layer ML1 and the material of the upper conductive layer UCL are mixed may be further prevented or reduced. However, a material included in the capping layer CPL is not necessarily limited thereto.

In an embodiment, a third thickness T3 of the capping layer CPL may be in a range of about 50 Å to about 200 Å. In an embodiment, a first thickness T1 of the upper conductive layer UCL may be in a range of about 50 Å to about 150 Å. For example, the third thickness T3 of the capping layer CPL may be about 100 Å. In case that the thickness of the capping layer CPL satisfies the above range, a phenomenon in which the material of the first metal layer ML1 and the material of the upper conductive layer UCL are mixed may be further prevented or reduced. The second conducive pattern CP2 may be readily manufactured in the process of manufacturing the display device DD. However, the third thickness T3 of the capping layer CPL is not necessarily limited thereto.

In an embodiment, the second metal layer ML2 may be disposed under the first metal layer ML1. For example, the second metal layer ML2 may be disposed between the first insulating layer IL1 and the first metal layer ML2.

The second metal layer ML2 may prevent or reduce a phenomenon in which hydrogen atom or the like is introduced into the active layer ACT. For example, the second metal layer ML2 may function as a hydrogen barrier. Accordingly, the second conductive pattern CP2 may prevent hydrogen from diffusing into the active layer ACT, thereby improving a performance of the transistor TR. Therefore, high resolution may be realized in the display device DD and display quality may be improved.

In an embodiment, the second metal layer ML2 may include titanium (Ti). In case that the second metal layer ML2 includes titanium (Ti), a phenomenon in which hydrogen or the like is introduced into the active layer ACT may be further prevented or reduced. However, a material included in the second metal layer ML2 is not necessarily limited thereto.

In an embodiment, a fourth thickness T4 of the second metal layer ML2 may be in a range of about 100 Å to about 300 Å. In an embodiment, a fourth thickness T4 of the second metal layer ML2 may be in a range of about 150 Å to about 250 Å. For example, the fourth thickness T4 of the second metal layer ML2 may be about 200 Å. In case that the thickness of the second metal layer ML2 satisfies the above range, a phenomenon in which hydrogen or the like is introduced into the active layer ACT may be further prevented or reduced. The second conductive pattern CP2 may be readily manufactured in the process of manufacturing the display device DD. However, the fourth thickness T4 of the second metal layer ML2 is not necessarily limited thereto.

FIG. 4 is a schematic cross-sectional view illustrating enlarged area A of FIG. 2 according to an embodiment. For example, FIG. 4 is a schematic cross-sectional view illustrating the second conductive pattern CP2 according to another embodiment.

Referring to FIGS. 1, 2 and 4, in an embodiment, the second metal layer ML2 may be omitted. For example, the lower conductive layer LCL may have a two-layer structure in which the first metal layer ML1 and the capping layer CPL are stacked. For example, the second conductive pattern CP2 may have a three-layer structure in which the first metal layer ML1, the capping layer CPL, and the upper conductive layer UCL are sequentially stacked. The first metal layer ML1 may contact (e.g., directly contact) the first insulating layer IL1.

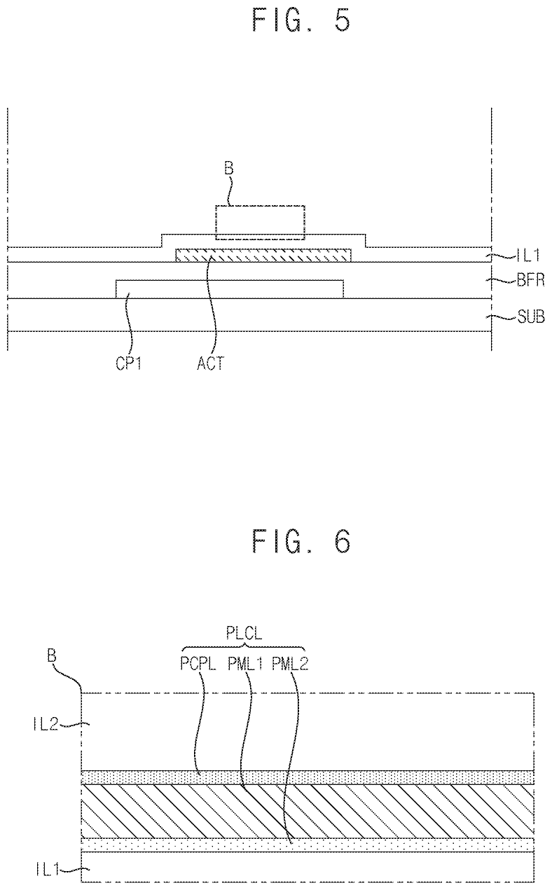

FIGS. 5 to 13 are schematic cross-sectional views illustrating a manufacturing method of a display device according to an embodiment. For example, FIGS. 5 to 13 may be schematic cross-sectional views illustrating a manufacturing method of manufacturing the display device DD described with reference to FIGS. 2 and 3. For example, hereinafter, referring to FIGS. 5 to 13, a manufacturing method of the display device DD will be described focusing on an embodiment that the second conductive pattern CP2 has a four-layer structure in which the second metal layer ML2, the first metal layer ML1, the capping layer CPL, and the upper conductive layer UCL are sequentially stacked.

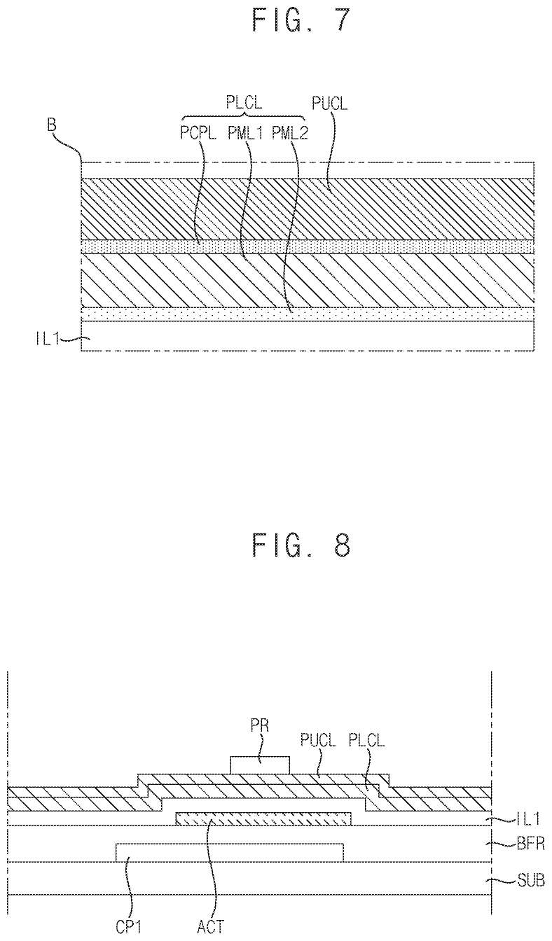

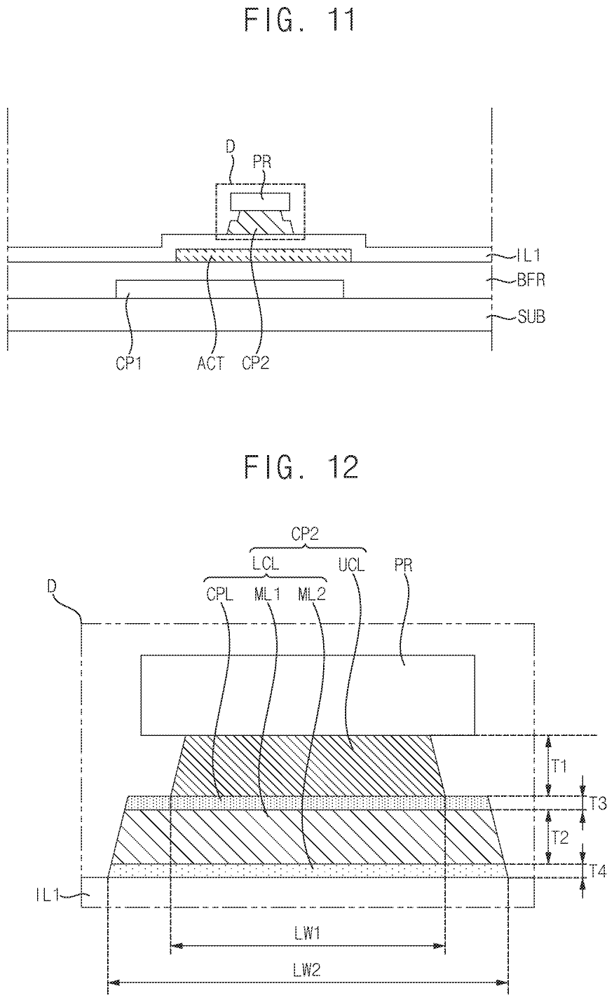

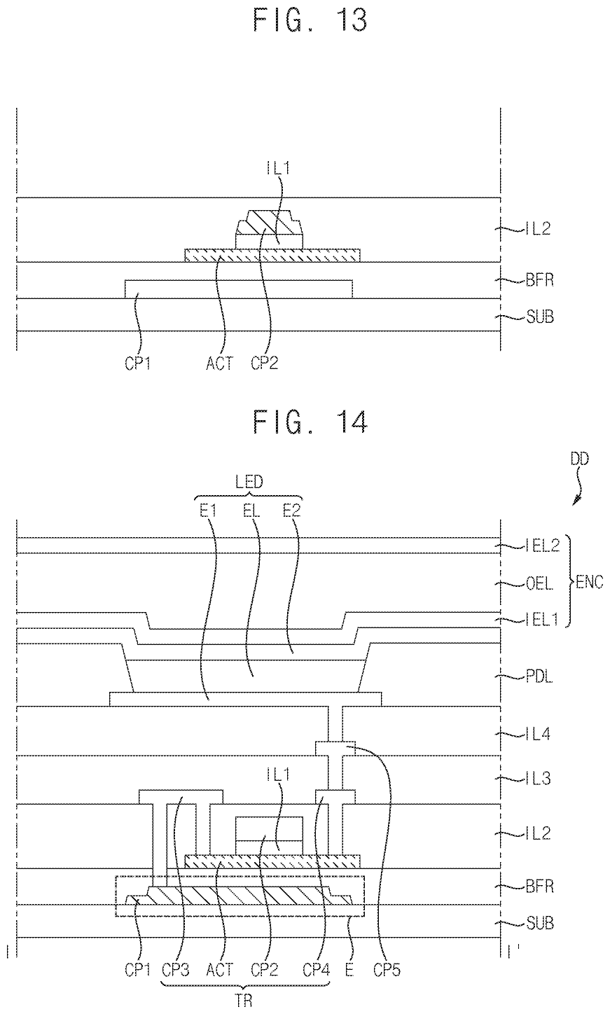

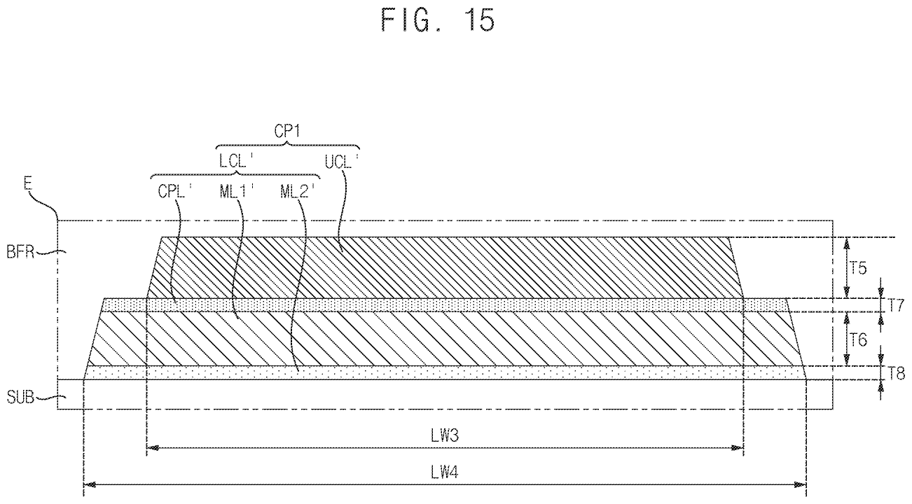

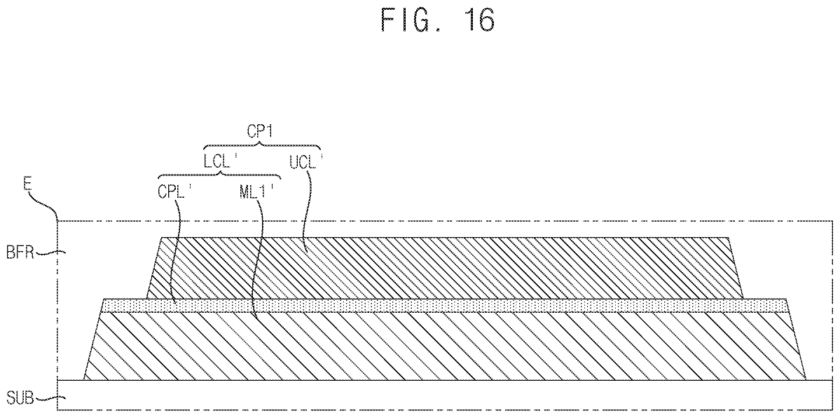

FIGS. 6 and 7 are cross-sectional views illustrating a detailed stacked structure by enlarging area B of FIG. 5, FIG. 11 is a cross-sectional view illustrating a detailed stacked structure by enlarging area C of FIG. 10, and FIG. 13 is a cross-sectional view illustrating a detailed stacked structure by enlarging area D of FIG. 12.

Referring to FIG. 5, the first conductive pattern CP1, the buffer layer BFR, the active layer ACT, and the first insulating layer IL1 may be formed on the substrate SUB.

Further referring to FIG. 6, a preliminary lower conductive layer PLCL may be formed on the first insulating layer IL1. The preliminary lower conductive layer PLCL may include a preliminary capping layer PCPL, a first preliminary metal layer PML1, and a second preliminary metal layer PML2. For example, the preliminary lower conductive layer PLCL may have a three-layer structure in which the second preliminary metal layer PML2, the first preliminary metal layer PML1, and the preliminary capping layer PCPL are sequentially stacked.

In an embodiment, the second preliminary metal layer PML2 may include titanium (Ti), the first preliminary metal layer PML1 may include aluminum (Al), and the preliminary capping layer PCPL may include a titanium alloy. For example, the preliminary capping layer PCPL may include titanium nitride (TiN). However, the disclosure is not necessarily limited thereto.

Further referring to FIG. 7, a preliminary upper conductive layer PUCL may be formed on the preliminary lower conductive layer PLCL. In an embodiment, the preliminary upper conductive layer PUCL may include copper (Cu).

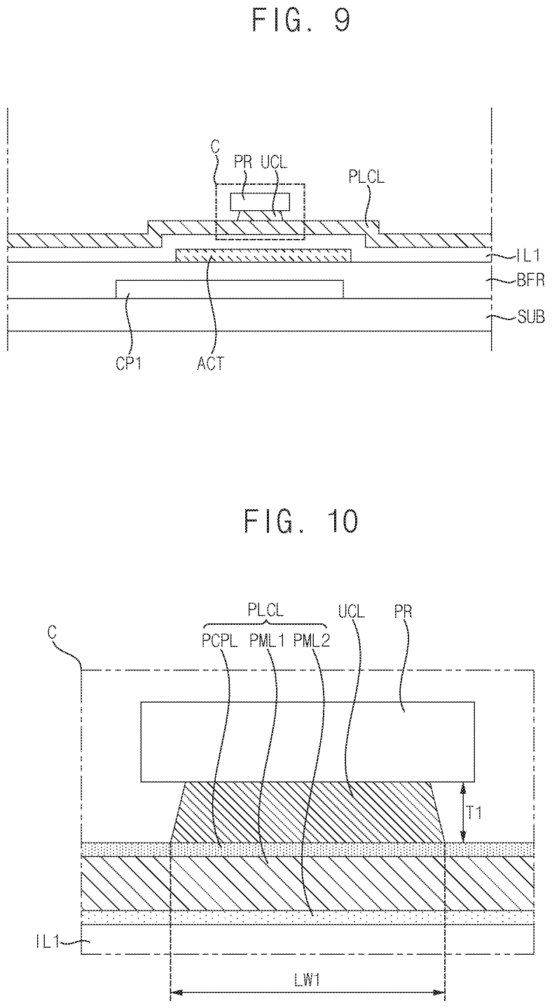

Referring to FIGS. 8 and 9, as a result, the preliminary lower conductive layer PLCL and the preliminary upper conductive layer PUCL may be sequentially formed on the first insulating layer IL1. After the forming of the preliminary lower conductive layer PLCL and the preliminary upper conductive layer PUCL, a photoresist pattern PR may be formed on the preliminary upper conductive layer PUCL. Referring to FIG. 9, the preliminary upper conductive layer PUCL may be patterned using the photoresist pattern PR as a mask. For example, the upper conductive layer UCL may be formed by patterning the preliminary upper conductive layer PUCL.

In an embodiment, a portion of the preliminary upper conductive layer PUCL may be etched through a wet etching process using an etchant or the like.

Further referring to FIG. 10, the upper conductive layer UCL may have the first line width LW1 and the first thickness T1. In an embodiment, the first thickness T1 of the upper conductive layer UCL may be in a range of about 1500 Å to about 3000 Å. In an embodiment, the first thickness T1 of the upper conductive layer UCL may be in a range of about 1500 Å to about 2000 Å. For example, the first thickness T1 of the upper conductive layer UCL may be about 1500 Å. In case that the first thickness T1 of the upper conductive layer UCL satisfies the above range, an etching time may be reduced and a manufacturing time of the display device DD may be reduced. Accordingly, manufacturing efficiency of the display device DD may be improved. In case that the first thickness T1 of the upper conductive layer UCL satisfies the above range, in the process of forming the upper conductive layer UCL, the first line width LW1 of the upper conductive layer UCL may be readily adjusted to be less than the second line width LW2 of the lower conductive layer LCL, which will be described below.

In an embodiment, an etching rate of the preliminary capping layer PCPL in the wet etching process may be less than an etching rate of the preliminary upper conductive layer PUCL in the wet etching process. For example, the preliminary capping layer PCPL may not be substantially etched by the wet etching process. Therefore, in the process of patterning the preliminary upper conductive layer PUCL, the preliminary capping layer PCPL may not be substantially damaged or removed. For example, in the process of patterning the preliminary upper conductive layer PUCL, the preliminary lower conductive layer PLCL may not be substantially damaged or removed.

Referring to FIGS. 11 and 12, the preliminary lower conductive layer PLCL may be patterned using the photoresist pattern PR as a mask. For example, the preliminary lower conductive layer PLCL may be patterned to form the lower conductive layer LCL. Accordingly, the second conductive pattern CP2 having a structure in which the lower conductive layer LCL and the upper conductive layer UCL are sequentially stacked may be formed.

In an embodiment, a portion of the preliminary lower conductive layer PLCL may be etched through a dry etching process using plasma or the like.

In an embodiment, the preliminary capping layer PCPL, the first preliminary metal layer PML1, and the second preliminary metal layer PML2 may be etched together by the dry etching process. For example, the preliminary capping layer PCPL may be patterned by the dry etching process to form the capping layer CPL, the first preliminary metal layer PML1 may be patterned to form the first metal layer ML1, and the second preliminary metal layer PML2 may be patterned to form the second metal layer ML2.

Accordingly, the lower conductive layer LCL may have a three-layer structure in which the second metal layer ML2, the first metal layer ML1, and the capping layer CPL are sequentially stacked. As a result, the second conductive pattern CP2 may have a four-layer structure in which the second metal layer ML2, the first metal layer ML1, the capping layer CPL, and the upper conductive layer UCL are sequentially stacked.

In an embodiment, the upper conductive layer UCL may include copper (Cu), and the first metal layer ML1 may include aluminum (Al). As the upper conductive layer UCL includes copper (Cu), a resistance of the second conductive pattern CP2 may be reduced. Also, since the first metal layer ML1 includes aluminum (Al), the second line width LW2 of the lower conductive layer LCL may be readily adjusted. For example, the line width of the second conductive pattern CP2 may be readily adjusted. Therefore, a fine line width of the second conductive pattern CP2 may be easily realized. Therefore, high resolution may be realized in the display device DD and display quality may be improved.

As described above, since the upper conductive layer UCL is formed by the wet etching process which is isotropic, a deviation may occur between an end of the photoresist pattern PR and an end of the upper conductive layer UCL. For example, skew may occur in the process of forming the upper conductive layer UCL. The skew may be a distance between the end of the photoresist pattern PR and the end of the upper conductive layer UCL. On the other hand, since the lower conductive layer LCL is formed by the dry etching process which is anisotropic, a deviation between the end of the photoresist pattern PR and an end of the upper conductive layer UCL may not substantially occur.

Accordingly, the lower conductive layer LCL may have the second line width LW2 greater than the first line width LW1 of the upper conductive layer UCL. For example, the side surface of the second conductive pattern CP2 may have a step. Accordingly, a step coverage of the second insulating layer (see, e.g., IL2 of FIG. 13) may be further improved during a process of forming the second insulating layer (see, e.g., IL2 of FIG. 13), which will be described below. Accordingly, durability of the display device DD may be improved.

In an embodiment, a difference between the second line width LW2 of the lower conductive layer LCL and the first line width LW1 of the upper conductive layer UCL may be in a range of about 0.3 micrometers to about 0.9 micrometers. In an embodiment, a difference between the second line width LW2 of the lower conductive layer LCL and the first line width LW1 of the upper conductive layer UCL may be in a range of about 0.5 micrometers to about 0.6 micrometers. For example, a difference between the second line width LW2 of the lower conductive layer LCL and the first line width LW1 of the upper conductive layer UCL may be about 0.5 micrometers. In case that a difference between the second line width LW2 of the lower conductive layer LCL and the first line width LW1 of the upper conductive layer UCL satisfies the above range, a step coverage of the second insulating layer (see, e.g., IL2 of FIG. 13) may be further improved.

In an embodiment, the second thickness T2 of the first metal layer ML1 may be in a range of about 1500 Å to about 3000 Å. In an embodiment, the second thickness T2 of the first metal layer ML1 may be in a range of about 1500 Å to about 2000 Å. For example, the second thickness T2 of the first metal layer ML1 may be about 1500 Å. Also, the third thickness T3 of the capping layer CPL may be in a range of about 50 Å to about 200 Å. In an embodiment, the second thickness T2 of the first metal layer ML1 may be in a range of about 50 Å to about 150 Å. For example, the third thickness T3 of the capping layer CPL may be about 100 Å. Also, the fourth thickness T4 of the second metal layer ML2 may be in a range of about 100 Å to about 300 Å. In an embodiment, the fourth thickness T4 of the second metal layer ML2 may be in a range of about 150 Å to about 250 Å. For example, the fourth thickness T4 of the second metal layer ML2 may be about 200 Å.

In case that the second thickness T2 of the first metal layer ML1, the third thickness T3 of the capping layer CPL, and the fourth thickness T4 of the second metal layer ML2 each satisfy the above range, etching time may be reduced, thereby manufacturing time of the display device DD may be reduced. Accordingly, manufacturing efficiency of the display device DD may be improved. However, the second thickness T2 of the first metal layer ML1, the third thickness T3 of the capping layer CPL, and the fourth thickness T4 of the second metal layer ML2 are not necessarily limited thereto.

In an embodiment, an etching rate of the upper conductive layer UCL in the dry etching process may be less than an etching rate of the preliminary lower conductive layer PLCL in the dry etching process. For example, the upper conductive layer UCL may not be substantially etched by the dry etching process. Therefore, in the process of forming the lower conductive layer LCL by patterning the preliminary lower conductive layer PLCL, the upper conductive layer UCL may not be substantially damaged or removed.

Referring to FIG. 13, after the second conductive pattern CP2 is formed, the photoresist pattern (see e.g., PR of FIG. 12) may be removed. Also, the first insulating layer IL1 may be patterned. However, the disclosure is not limited thereto, and in another embodiment, the first insulating layer IL1 may be formed (e.g., entirely formed) on the buffer layer BFR.

After the patterning of the first insulating layer IL1, the second insulating layer IL2 covering the second conductive pattern CP2 may be formed on the buffer layer BFR. Referring to FIG. 12, the second conductive pattern CP2 may have a structure in which the lower conductive layer LCL and the upper conductive layer UCL are sequentially stacked, and the first line width LW1 of the upper conductive layer UCL may be less than the second line width LW2 of the lower conductive layer LCL. Accordingly, step coverage of the second insulating layer IL2 may be improved. Thus, cracks in the second insulating layer IL2 may be prevented or reduced. Accordingly, durability of the display device DD may be improved.

As shown in FIG. 2, the third conductive pattern CP3, the fourth conductive pattern CP4, the third insulating layer IL3, the fifth conductive pattern CP5, the fourth insulating layer IL4, the light emitting element LED, the pixel defining layer PDL, and the encapsulation layer ENC may be formed on the second insulating layer IL2.

Although not illustrated, a manufacturing method of the display device DD of FIGS. 2 and 4 and the manufacturing method of the display device DD of FIGS. 5 to 13 may be formed by substantially a same method except for omitting the second preliminary metal layer (see, e.g., PML2 of FIG. 6) from the preliminary lower conductive layer (see, e.g., PLCL of FIG. 6). Therefore, a detailed description will be omitted.

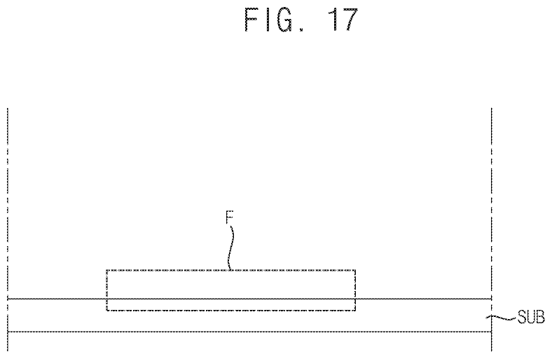

FIG. 14 is a schematic cross-sectional view taken along line I-I′ of FIG. 1 according to an embodiment, and FIG. 15 is a schematic cross-sectional view illustrating enlarged area E of FIG. 14 according to an embodiment. For example, FIG. 14 may correspond to the cross-sectional view of FIG. 2, and FIG. 15 may be a schematic cross-sectional view illustrating the first conductive pattern CP1 of FIG. 14 according to an embodiment.

Referring to FIGS. 1, 14, and 15, in an embodiment, the first conductive pattern CP1 may include an upper conductive layer UCL′ and a lower conductive layer LCL′. The lower conductive layer LCL′ may be disposed on the substrate SUB, and the upper conductive layer UCL′ may be disposed on the lower conductive layer LCL′. For example, the first conductive pattern CP1 may have a multi-layered structure in which the lower conductive layer LCL′ and the upper conductive layer UCL′ are sequentially stacked. In an embodiment, the upper conductive layer UCL′ may have a third line width LW3, and the lower conductive layer LCL′ may have a fourth line width LW4 greater than the third line width LW3.

For example, the upper conductive layer UCL′ may expose a portion of an upper surface of the lower conductive layer LCL′ and may be disposed on the lower conductive layer LCL′. For example, a side surface of the first conductive pattern CP1 may have a step. Accordingly, step coverage of the buffer layer BFR covering the first conductive pattern CP1 may be improved. Therefore, cracks of the buffer layer BFR may be prevented or reduced, and damage to the first conductive pattern CP1 may be prevented or reduced. Accordingly, durability of the display device DD may be improved.

In an embodiment, a difference between the fourth line width LW4 of the lower conductive layer LCL′ and the third line width LW3 of the upper conductive layer UCL′ may be in a range of about 0.3 micrometers to about 0.9 micrometers. In an embodiment, a difference between the fourth line width LW4 of the lower conductive layer LCL′ and the third line width LW3 of the upper conductive layer UCL′ may be in a range of about 0.5 micrometers to about 0.6 micrometers. For example, a difference between the fourth line width LW4 of the lower conductive layer LCL′ and the third line width LW3 of the upper conductive layer UCL′ may be about 0.5 micrometers. In case that a difference between the fourth line width LW4 of the lower conductive layer LCL′ and the third line width LW3 of the upper conductive layer UCL′ satisfies the above range, step coverage of the buffer layer BFR may be further improved. Accordingly, durability of the display device DD may be further improved.

A material included in the upper conductive layer UCL′ of FIG. 15 and a material included in the upper conductive layer UCL of FIG. 3 may be substantially the same. Also, a fifth thickness T5 of the upper conductive layer UCL′ of FIG. 15 and the first thickness T1 of the upper conductive layer UCL of FIG. 3 may be substantially the same. Therefore, a detailed description will be omitted.

The lower conductive layer LCL′ may include a capping layer CPL′, a first metal layer ML1′, and a second metal layer ML2′. For example, the lower conductive layer LCL′ may have a three-layer structure in which the second metal layer ML2′, the first metal layer ML1′, and the capping layer CPL′ are sequentially stacked. For example, the first conductive pattern CP1 may have a four-layer structure in which the second metal layer ML2′, the first metal layer ML1′, the capping layer CPL′, and the upper conductive layer UCL′ are sequentially stacked.

A material included in the capping layer CPL′, a material included in the first metal layer ML1′, and a material included in the second metal layer ML2′ of FIG. 15 and a material included in the capping layer CPL, a material included in the first metal layer ML1, and a material included in the second metal layer ML2 of FIG. 3 may be substantially the same, respectively. Therefore, a detailed description will be omitted.

A sixth thickness T6 of the first metal layer ML1′, a seventh thickness T7 of the capping layer CPL′, and an eighth thickness T8 of the second metal layer ML2′ of FIG. 15 and the second thickness T2 of the first metal layer ML1, the third thickness T3 of the capping layer CPL, and the fourth thickness T4 of the second metal layer ML2 of FIG. 3 may be substantially the same, respectively. Therefore, a detailed description will be omitted.

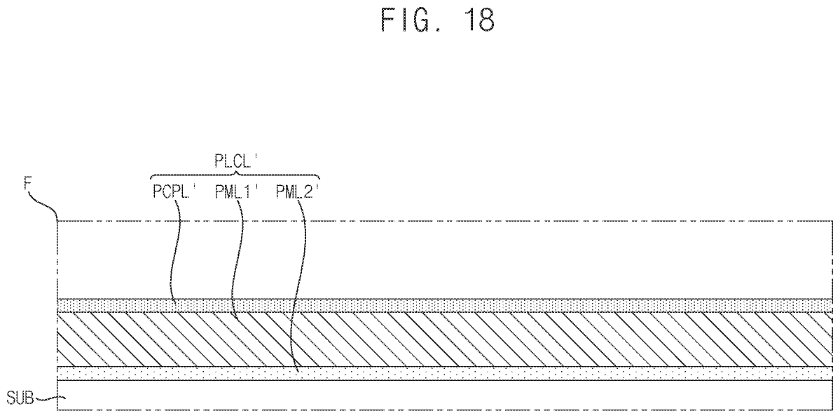

FIG. 16 is a schematic cross-sectional view illustrating enlarged area E of FIG. 14 according to an embodiment. For example, FIG. 16 is a schematic cross-sectional view illustrating the first conductive pattern CP1 of FIG. 14 according to another embodiment.

Referring to FIGS. 1, 14, and 16, in an embodiment, the second metal layer ML2′ may be omitted. For example, the lower conductive layer LCL′ may have a two-layer structure in which the first metal layer ML1′ and the capping layer CPL′ are stacked. For example, the first conductive pattern CP1 may have a three-layer structure in which the first metal layer ML1′, the capping layer CPL′, and the upper conductive layer UCL′ are sequentially stacked, and the first metal layer ML1′ may contact (e.g., directly contact) the substrate SUB.

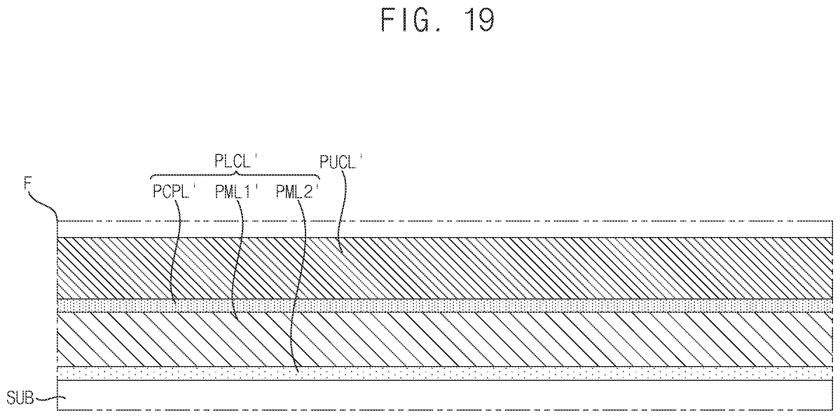

FIGS. 17 to 25 are schematic cross-sectional views illustrating a manufacturing method of a display device according to an embodiment.

For example, FIGS. 17 to 25 may be schematic cross-sectional views illustrating a manufacturing method of the display device DD described with reference to FIGS. 14 and 15. For example, hereinafter, referring to FIGS. 17 to 25, a manufacturing method of the display device DD will be described focusing on an embodiment that the first conductive pattern CP1 has a four-layer structure in which the second metal layer ML2′, the first metal layer ML1′, the capping layer CPL′, and the upper conductive layer UCL′ are sequentially stacked.

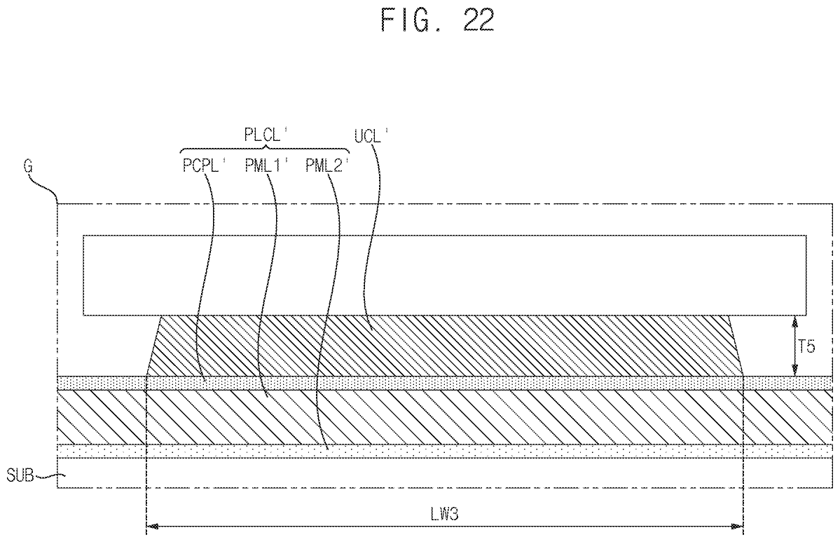

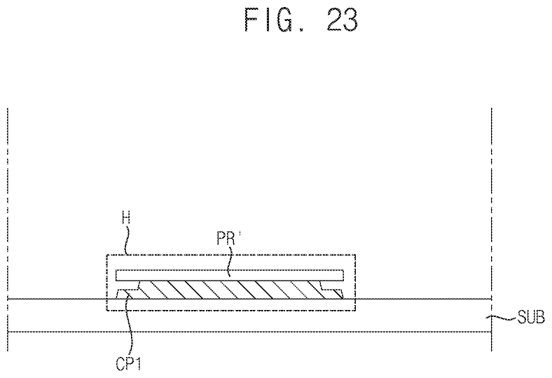

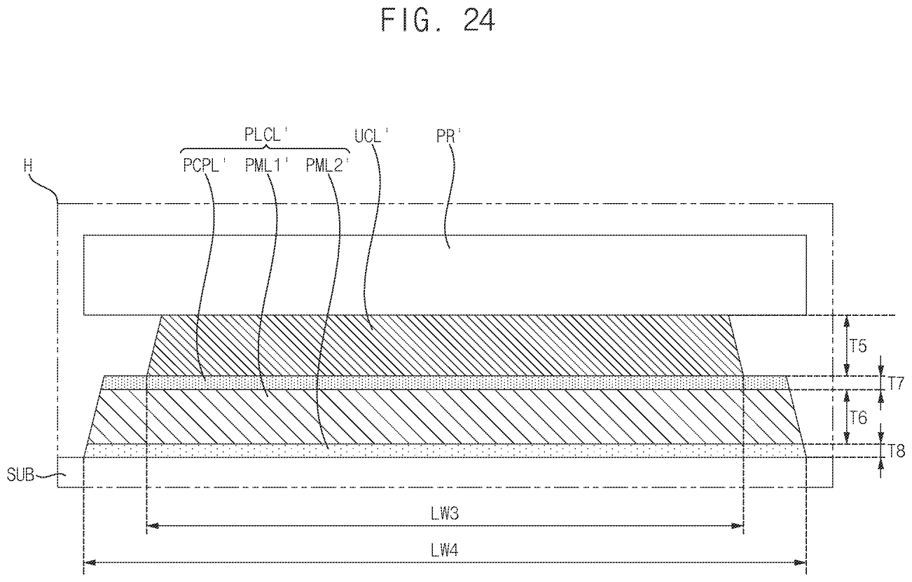

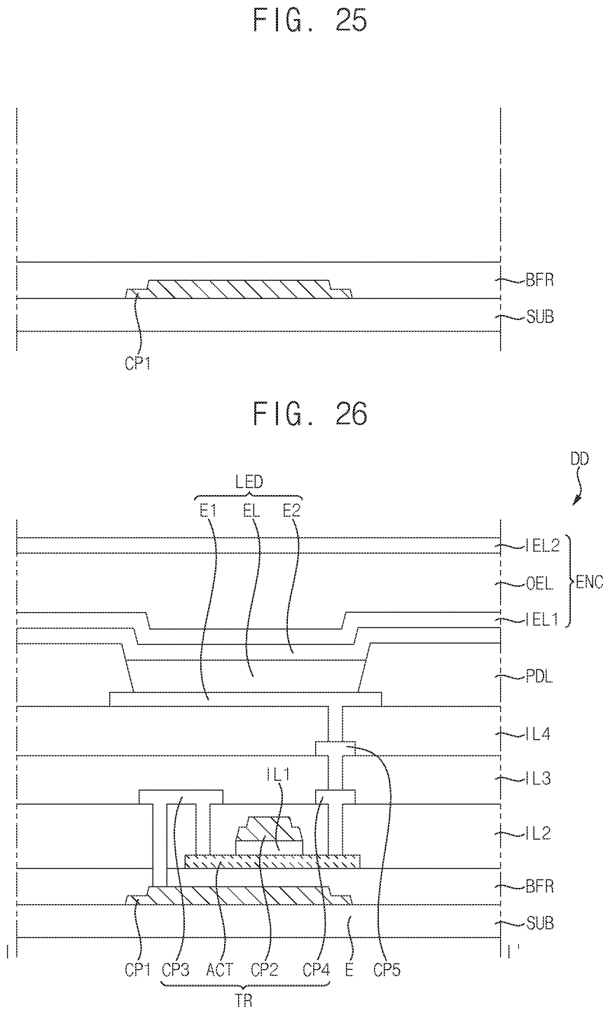

FIGS. 18 and 19 are cross-sectional views illustrating a detailed stacked structure by enlarging area F of FIG. 17, FIG. 22 is a cross-sectional view illustrating a detailed stacked structure by enlarging area G of FIG. 21, and FIG. 24 is a cross-sectional view illustrating a detailed stacked structure by enlarging area H of FIG. 23.

Referring to FIGS. 17 and 18, a preliminary lower conductive layer PLCL′ may be formed on the substrate SUB. The preliminary lower conductive layer PLCL′ may include a preliminary capping layer PCPL′, a first preliminary metal layer PML1′, and a second preliminary metal layer PML2′. For example, the preliminary lower conductive layer PLCL′ may have a three-layer structure in which the second preliminary metal layer PML2′, the first preliminary metal layer PML1′, and the preliminary capping layer PCPL′ are sequentially stacked.

In an embodiment, the second preliminary metal layer PML2′ may include titanium (Ti), the first preliminary metal layer PML1′ may include aluminum (Al), and the preliminary capping layer PCPL′ may include a titanium alloy. For example, the preliminary capping layer PCPL′ may include titanium nitride (TiN). However, the disclosure is not necessarily limited thereto.

Referring further to FIG. 19, a preliminary upper conductive layer PUCL′ may be formed on the preliminary lower conductive layer PLCL′. In an embodiment, the preliminary upper conductive layer PUCL′ may include copper (Cu).

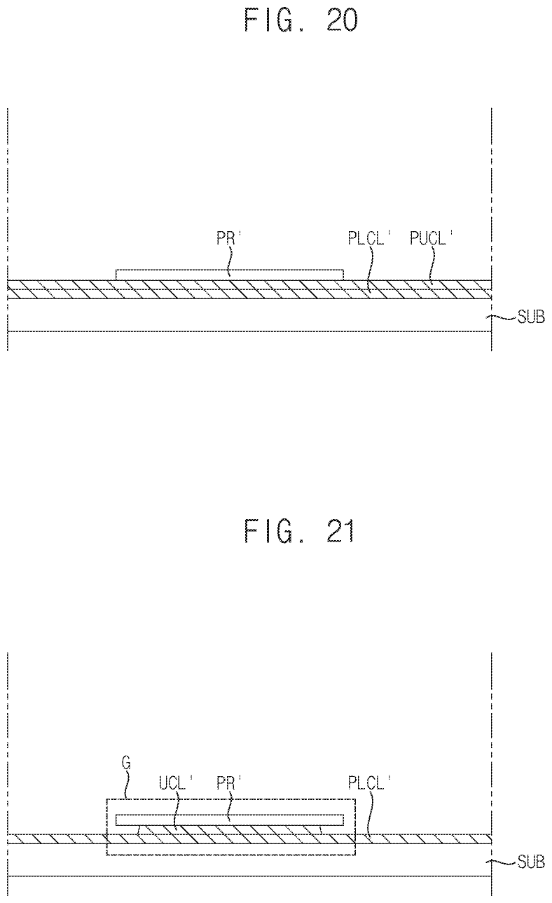

Referring to FIGS. 20 and 21, as a result, the preliminary lower conductive layer PLCL′ and the preliminary upper conductive layer PUCL′ may be sequentially formed on the substrate SUB. After the forming of the preliminary lower conductive layer PLCL′ and the preliminary upper conductive layer PUCL′, a photoresist pattern PR′ may be formed on the preliminary upper conductive layer PUCL′. Referring to FIG. 21, the preliminary upper conductive layer PUCL′ may be patterned using the photoresist pattern PR′ as a mask. For example, the upper conductive layer UCL′ may be formed by patterning the preliminary upper conductive layer PUCL′.

In an embodiment, a portion of the preliminary upper conductive layer PUCL′ may be etched through a wet etching process using an etchant or the like.

Further referring to FIG. 22, the upper conductive layer UCL′ may have the third line width LW3 and the fifth thickness T5.

In an embodiment, an etching rate of the preliminary capping layer PCPL′ in the wet etching process may be less than an etching rate of the preliminary upper conductive layer PUCL′ in the wet etching process. For example, the preliminary capping layer PCPL′ may not be substantially etched by the wet etching process. Therefore, in the process of patterning the preliminary upper conductive layer PUCL′, the preliminary capping layer PCPL may not be substantially damaged or removed. For example, in the process of patterning the preliminary upper conductive layer PUCL′, the preliminary lower conductive layer PLCL′ may not be substantially damaged or removed.

Referring to FIGS. 23 and 24, the preliminary lower conductive layer PLCL′ may be patterned using the photoresist pattern PR′ as a mask. For example, the preliminary lower conductive layer PLCL′ may be patterned to form the lower conductive layer LCL′. Accordingly, the first conductive pattern CP1 having a structure in which the lower conductive layer LCL′ and the upper conductive layer UCL′ are sequentially stacked may be formed.

In an embodiment, a portion of the preliminary lower conductive layer PLCL′ may be etched through a dry etching process using plasma or the like.

In an embodiment, the preliminary capping layer PCPL′, the first preliminary metal layer PML1′, and the second preliminary metal layer PML2′ may be etched together by the dry etching process. For example, the preliminary capping layer PCPL′ may be patterned by the dry etching process to form the capping layer CPL′, the first preliminary metal layer PML′ may be patterned to form the first metal layer ML1′, and the second preliminary metal layer PML2′ may be patterned to form the second metal layer ML2′.

Accordingly, the lower conductive layer LCL′ may have a three-layer structure in which the second metal layer ML2′, the first metal layer ML1′, and the capping layer CPL′ are sequentially stacked. As a result, the first conductive pattern CP1 may be formed as a four-layer structure in which the second metal layer ML2′, the first metal layer ML1′, the capping layer CPL′, and the upper conductive layer UCL′ are sequentially stacked.

In an embodiment, the upper conductive layer UCL′ may include copper (Cu), and the first metal layer ML1′ may include aluminum (Al). As the upper conductive layer UCL′ includes copper (Cu), a resistance of the first conductive pattern CP1 may be reduced. Also, since the first metal layer ML1′ includes aluminum (Al), the fourth line width LW4 of the lower conductive layer LCL may be readily adjusted. For example, the line width of the first conductive pattern CP1 may be readily adjusted. Therefore, a fine line width of the first conductive pattern CP1 may be readily realized. Therefore, high resolution may be realized in the display device DD and display quality may be improved.

As described above, since the upper conductive layer UCL′ is formed by the wet etching process which is isotropic, a deviation may occur between an end of the photoresist pattern PR′ and an end of the upper conductive layer UCL′. For example, skew may occur in the process of forming the upper conductive layer UCL′. The skew may be a distance between the end of the photoresist pattern PR′ and the end of the upper conductive layer UCL′. On the other hand, since the lower conductive layer LCL′ is formed by the dry etching process which is anisotropic, a deviation between the end of the photoresist pattern PR′ and an end of the upper conductive layer UCL′ may not substantially occur.

Accordingly, the lower conductive layer LCL′ may have the fourth line width LW4 greater than the third line width LW3 of the upper conductive layer UCL. For example, the side surface of the first conductive pattern CP1 may have a step. Accordingly, a step coverage of the buffer layer BFR may be further improved during a process of forming the buffer layer (see, e.g., BFR of FIG. 25), which will be described below. Accordingly, durability of the display device DD may be improved.

Referring to FIG. 25, after the first conductive pattern CP1 is formed, the photoresist pattern (see, e.g., PR′ of FIG. 24) may be removed. Also, the buffer layer BFR covering the first conductive pattern CP1 may be formed on the substrate SUB. Referring to FIG. 24, the first conductive pattern CP1 may have a structure in which the lower conductive layer LCL′ and the upper conductive layer UCL′ are sequentially stacked, and the third line width LW3 of the upper conductive layer UCL′ may be less than the fourth line width LW4 of the lower conductive layer LCL′. Accordingly, step coverage of the buffer layer BFR may be improved. Thus, cracks in the buffer layer BFR may be prevented or reduced. Accordingly, durability of the display device DD may be improved.

Referring to FIG. 14, the active layer ACT, the first insulating layer IL1, the second conductive pattern CP2, the second insulating layer IL2, the third conductive pattern CP3, the fourth conductive pattern CP4, the third insulating layer IL3, the fifth conductive pattern CP5, the fourth insulating layer IL4, the light emitting element LED, the pixel defining layer PDL, and the encapsulation layer ENC may be formed on the buffer layer BFR.

Although not illustrated, a manufacturing method of the display device DD of FIGS. 14 and 16 and the manufacturing method of the display device DD of FIGS. 17 to 25 may be formed by substantially the same method except for omitting the second preliminary metal layer (see, e.g., PML2′ of FIG. 18) from the preliminary lower conductive layer (see, e.g., PLCL′ of FIG. 18). Therefore, a detailed description will be omitted.

FIG. 26 is a schematic cross-sectional view taken along line I-I′ of FIG. 1 according to an embodiment. For example, FIG. 26 may correspond to the cross-sectional view of FIG. 2.

Referring to FIGS. 1 and 26, in an embodiment, both the first conductive pattern CP1 and the second conductive pattern CP2 may have a multi-layered structure. For example, the first conductive pattern CP1 may have a four-layer structure in which the second metal layer (see, e.g., ML2′ of FIG. 15), the first metal layer (see, e.g., ML1′ of FIG. 15), the capping layer (see, e.g., CPL′ of FIG. 15), and the upper conductive layer (see, e.g., UCL′ of FIG. 15), and the second conductive pattern CP2 may have a four-layer structure in which the second metal layer (see, e.g., ML2 of FIG. 3), the first metal layer (see, e.g., ML1 of FIG. 3), the capping layer (see, e.g., CPL of FIG. 3), and the upper conductive layer (see, e.g., UCL of FIG. 3) are sequentially stacked. In another embodiment, the first conductive pattern CP1 may have a three-layer structure in which the first metal layer (see, e.g., ML1′ of FIG. 16), the capping layer (see, e.g., CPL′ of FIG. 16), and the upper conductive layer (see, e.g., UCL′ of FIG. 16) are sequentially stacked, and the second conductive pattern CP2 may have a three-layer structure in which the first metal layer (see, e.g., ML1 of FIG. 4), the capping layer (see, e.g., CPL of FIG. 4), and the upper conductive layer (see, e.g., UCL of FIG. 4) are sequentially stacked.

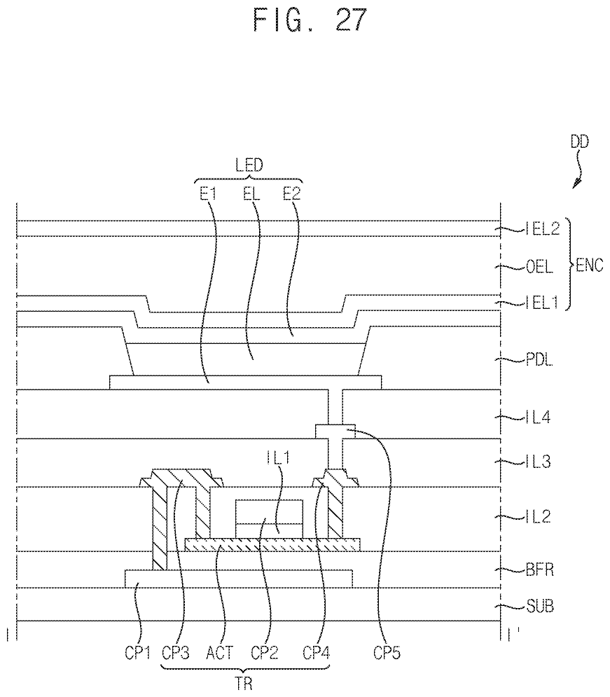

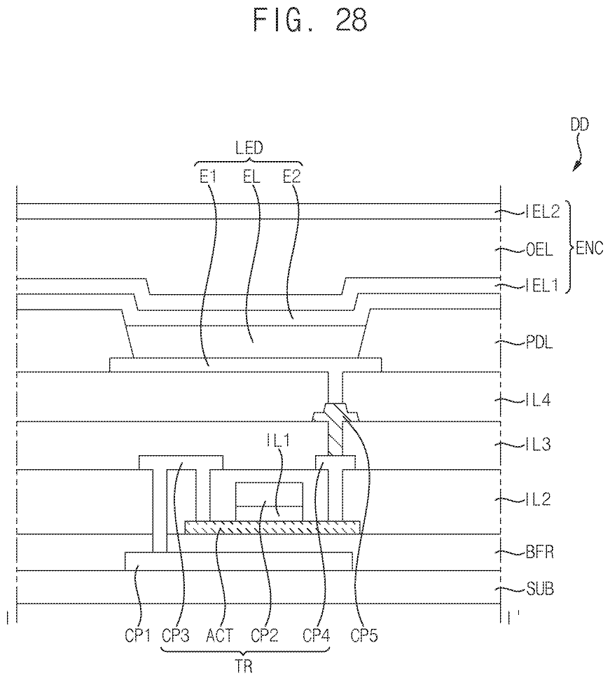

FIG. 27 is a schematic cross-sectional view taken along line I-I′ of FIG. 1 according to an embodiment. For example, FIG. 27 may correspond to the cross-sectional view of FIG. 2.

Referring to FIGS. 1 and 27, in an embodiment, each of the third conductive pattern CP3 and the fourth conductive pattern CP4 and the second conductive pattern CP2 of FIGS. 2 to 4 may have a substantially same stacked structure. For example, each of the third conductive pattern CP3 and the fourth conductive pattern CP4 may have a side surface having a step.

Although the side surface of the first conductive pattern CP1 and the side surface of the second conductive pattern CP2 are illustrated as not having a step in FIG. 27, the disclosure is not necessarily limited thereto. For example, even in case that each of the third conductive pattern CP3 and the fourth conductive pattern CP4 and the second conductive pattern CP2 of FIGS. 2 and 3 have substantially the same stacked structure, the first conductive pattern CP1 may have the stacked structure of FIGS. 14 to 16, and the second conductive pattern CP2 may have the stacked structure of FIGS. 2 to 4.

FIG. 28 is a schematic cross-sectional view taken along line I-I′ of FIG. 1 according to an embodiment. For example, FIG. 28 may correspond to the cross-sectional view of FIG. 2.

Referring to FIGS. 1 and 28, in an embodiment, the fifth conductive pattern CP5 and the second conductive pattern CP2 of FIGS. 2 to 4 may have a substantially same stacked structure. For example, the fifth conductive pattern CP5 may have a side surface having a step.

Although the side surface of the first conductive pattern CP1 and the side surface of the second conductive pattern CP2 are illustrated as not having a step in FIG. 28, the disclosure is not necessarily limited thereto. For example, even in case that the fifth conductive pattern CP5 and the second conductive pattern CP2 described with reference to FIGS. 2 and 3 have substantially the same stacked structure, the first conductive pattern CP1 may have the stacked structure of FIGS. 14 to 16, and the second conductive pattern CP2 may have the stacked structure of FIGS. 2 to 4.

According to embodiments, the display device DD may include a conductive pattern CP1 to CP5 disposed on or under the active layer ACT, and the conductive pattern CP1 to CP5 may have a multi-layered structure in which a lower conductive layer LCL and an upper conductive layer UCL are sequentially stacked. The lower conductive layer LCL may have a high etching rate in the dry etching process, but a low etching rate in the wet etching process. For example, the upper conductive layer UCL may have a high etching rate in the wet etching process, but a low etching rate in the dry etching process.

Accordingly, a second line width LW2 of the lower conductive layer LCL may be greater than a first line width LW1 of the upper conductive layer UCL. For example, a side surface of the conductive pattern CP1 to CP5 may have a step. Accordingly, step coverage of an insulating layer covering the conductive pattern CP1 to CP5 may be improved. Thus, cracks in the insulating layer may be prevented or reduced, and damage to the conductive pattern CP1 to CP5 may be prevented or reduced. Accordingly, durability of the display device DD may be improved.

Also, the upper conductive layer UCL may have low resistance characteristics. Accordingly, a resistance of the conductive pattern CP1 to CP5 may be reduced due to the low resistance characteristics of the upper conductive layer UCL, and at the same time, in the process of forming the lower conductive layer LCL using the dry etching process, a fine line width of the conductive pattern CP1 to CP5 may be easily realized. Therefore, high resolution may be realized in the display device DD and display quality may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
an active layer disposed on a substrate; and
a conductive pattern disposed on or under the active layer and including:
an upper conductive layer having a first line width in a direction; and
a lower conductive layer including:
a first metal layer disposed under the upper conductive layer; and
a capping layer disposed between the upper conductive layer and the first metal layer and having a second line width in the direction greater than the first line width.

2. The display device of claim 1, wherein a side surface of the conductive pattern has a step.

3. The display device of claim 1, wherein
the upper conductive layer includes copper, and
the first metal layer includes aluminum.

4. The display device of claim 1, wherein a difference between the second line width and the first line width is in a range of about 0.3 micrometers to about 0.9 micrometers.

5. The display device of claim 1, wherein
a thickness of the upper conductive layer is in a range of about 1500 Å to about 3000 Å, and
a thickness of the lower conductive layer is in a range of about 1500 Å to about 3000 Å.

6. The display device of claim 1, wherein the capping layer includes a titanium alloy.

7. The display device of claim 6, wherein the capping layer includes titanium nitride.

8. The display device of claim 1, wherein the lower conductive layer further includes a second metal layer disposed under the first metal layer.

9. The display device of claim 8, wherein the second metal layer includes titanium.

10. The display device of claim 1, further comprising:
an insulating layer disposed between the active layer and the conductive pattern,
wherein the active layer and the conductive pattern are spaced apart from each other by the insulating layer.

11. A method of manufacturing a display device, the method comprising:
forming an active layer on a substrate; and
forming a conductive pattern on or under the active layer,
wherein the forming of the conductive pattern includes:
forming a preliminary lower conductive layer including a first preliminary metal layer and a preliminary capping layer disposed on the first preliminary metal layer;
forming a preliminary upper conductive layer on the preliminary lower conductive layer;
forming an upper conductive layer having a first line width in a direction by patterning the preliminary upper conductive layer; and
forming a lower conductive layer including a first metal layer disposed under the upper conductive layer and a capping layer disposed between the upper conductive layer and the first metal layer and having a second line width in the direction greater than the first line width by patterning the preliminary lower conductive layer.

12. The method of claim 11, wherein
the forming of the upper conductive layer includes etching a portion of the preliminary upper conductive layer through a wet etching process, and
the forming of the lower conductive layer includes etching a portion of the preliminary lower conductive layer through a dry etching process.

13. The method of claim 12, wherein an etching rate of the preliminary capping layer in the wet etching process is less than an etching rate of the preliminary upper conductive layer in the wet etching process.

14. The method of claim 12, wherein the preliminary capping layer and the first preliminary metal layer are etched together through the dry etching process.

15. The method of claim 11, wherein
the preliminary upper conductive layer includes copper, and
the first preliminary metal layer includes aluminum.

16. The method of claim 11, wherein the preliminary capping layer includes a titanium alloy.

17. The method of claim 11, wherein a difference between the second line width and the first line width is in a range of about 0.3 micrometer to about 0.9 micrometer.

18. The method of claim 11, wherein
the preliminary lower conductive layer further includes a second preliminary metal layer disposed under the first preliminary metal layer, and
the lower conductive layer further includes a second metal layer disposed under the first metal layer after the forming of the lower conductive layer.

19. The method of claim 18, wherein the second preliminary metal layer includes titanium.

20. The method of claim 11, wherein after the forming of the conductive pattern, a side surface of the conductive pattern has a step.
